(19) United States
(12) Patent Application Publication
(10) Pub. No.: US 2025/0167161 A1
(43) Pub. Date: May 22, 2025

(54) INTEGRATED CIRCUIT PACKAGE AND METHOD

(71) Applicant: Taiwan Semiconductor Manufacturing Co., Ltd., Hsinchu (TW)

(72) Inventors: Yu-Jin Hu, Taoyuan (TW); Hua-Wei Tseng, New Taipei (TW); Wei-Cheng Wu, Hsinchu (TW); Yung-Ping Chiang, Zhubei (TW); An-Jhih Su, Taoyuan (TW); Der-Chyang Yeh, Hsinchu (TW)

(21) Appl. No.: 18/585,854

(22) Filed: Feb. 23, 2024

Related U.S. Application Data
(60) Provisional application No. 63/599,585, filed on Nov. 16, 2023.

(51) Int. Cl. H01L 23/00; H01L 23/498; H01L 25/065; H01L 25/18

(52) U.S. Cl. CPC H01L 24/32; H01L 23/49822; H01L 24/16; H01L 24/73; H01L 24/83; H01L 25/0652; H01L 25/18; H01L 2224/16225; H01L 2224/32225; H01L 2224/73204; H01L 2224/83894; H01L 2924/1431; H01L 2924/181

(57) ABSTRACT

A package includes a first die over and bonded to a first side of a package component, where a first bond between the first die and the package component includes a dielectric-to-dielectric bond between a first bonding layer of the first die and a second bonding layer on the package component, and second bonds between the first die and the package component include metal-to-metal bonds between first bonding pads of the first die and second bonding pads on the package component, a first portion of a redistribution structure adjacent to the first die and over the second bonding layer, and a second die over and coupled to the first portion of the redistribution structure using first conductive connectors, where the first conductive connectors are electrically connected to first conductive pads in the second bonding layer.

### CROSS-REFERENCE TO RELATED APPLICATIONS

This application claims priority to U.S. Application No. 63/599,585, filed on Nov. 16, 2023, which application is hereby incorporated herein by reference.

### BACKGROUND

Since the development of the integrated circuit (IC), the semiconductor industry has experienced continued rapid growth due to continuous improvements in the integration density of various electronic components (i.e., transistors, diodes, resistors, capacitors, etc.). For the most part, these improvements in integration density have come from repeated reductions in minimum feature size, which allows more components to be integrated into a given area.

These integration improvements are essentially two-dimensional (2D) in nature, in that the area occupied by the integrated components is essentially on the surface of the semiconductor wafer. The increased density and corresponding decrease in area of the integrated circuit has generally surpassed the ability to bond an integrated circuit chip directly onto a substrate. Interposers have been used to redistribute ball contact areas from that of the chip to a larger area of the interposer. Further, interposers have allowed for a three-dimensional (3D) package that includes multiple chips. Other packages have also been developed to incorporate 3D aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 4A illustrate cross-sectional views of intermediate steps during a process for forming a device package, in accordance with some embodiments.

FIG. 4B illustrates a cross-sectional view of intermediate steps during a process for forming a device package, in accordance with alternate embodiments.

FIG. 5A illustrates a cross-sectional view of intermediate steps during a process for forming a device package, in accordance with some embodiments.

FIG. 5B illustrates a cross-sectional view of intermediate steps during a process for forming a device package, in accordance with alternate embodiments.

FIG. 6 illustrates a cross-sectional view of intermediate steps during a process for forming a device package, in accordance with some embodiments.

FIGS. 7A-7B illustrates cross-sectional views of intermediate steps during a process for forming a device package, in accordance with alternate embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments include methods applied to the formation of a device package. The method comprises bonding at least one first semiconductor die (e.g., a first top die) to an interposer using a hybrid bonding configuration, wherein first bonding pads of the first semiconductor die are bonded to and electrically connected to second bonding pads on the interposer through direct metal-to-metal bonding. The hybrid bonding configuration also comprises directly bonding a first bonding layer of the first semiconductor die to a second bonding layer on the interposer using a dielectric-to-dielectric bond. The method further comprises coupling and electrically connecting at least one second semiconductor die (e.g., a second top die) to the interposer using first conductive connectors, such as micro bumps, or the like. The first bonding pads and the second bonding pads may have a first pitch that is less than 9 μm, wherein the first pitch is a distance from the center of a first bonding pad or a second bonding pad to the center of an adjacent first bonding pad or second bonding pad, respectively. The first conductive connectors may have a second pitch (e.g., greater than 30 μm) that is greater than the first pitch, wherein the second pitch is a distance from the center of a first conductive connector to the center of an adjacent first conductive connector. One or more embodiments disclosed herein may allow the bonding of semiconductor dies having different interconnection bandwidth requirements to the interposer. For example, the first semiconductor die may be a graphics processing unit (GPU), central processing unit (CPU), or the like that requires a high input/output signal transfer capability. Because the first pitch is less than 9 μm, a greater number of the first bonding pads and second bonding pads that bond the first semiconductor die to the interposer can be utilized per unit area of the first semiconductor die and the interposer, which allows for greater interconnection bandwidths and faster signal transmission between the first semiconductor die and the interposer. As a result of the greater number of the first bonding pads and second bonding pads being utilized per unit area of the first semiconductor die and the interposer, a size of the device package can be reduced as compared to if other types of conductive connectors (e.g., solder bumps) having a greater pitch than the first pitch are used to bond the first semiconductor die to the interposer. The second semiconductor die may be a memory die, or the like, that may not require as high a signal transfer capability. It then becomes sufficient to use the first conductive connectors that have the second pitch to couple the second semiconductor die to the interposer, while still fulfilling interconnection bandwidth requirements. In addition, the use of the first conductive connectors to couple the second semiconductor die to the interposer results in lower manufacturing costs, and also results in better electrical connection between the second semiconductor die and the interposer, which improves device yield and reliability. Therefore, forming the device package by combining the use of the first and second bonding pads and the first and second bonding layers to bond the first semiconductor die (e.g., having high interconnection bandwidth requirements) to the interposer, and using the first conductive connectors to couple the second semiconductor die (e.g., having lower interconnection bandwidth requirements than the first semiconductor die) to the interposer may allow for the overall reduction of the device package size, a reduction in manufacturing costs, and an improved device yield and reliability of the device package.

Embodiments discussed herein are to provide examples to enable making or using the subject matter of this disclosure, and a person having ordinary skill in the art will readily understand modifications that can be made while remaining within contemplated scopes of different embodiments. Like reference numbers and characters in the figures below refer to like components. Although method embodiments may be discussed as being performed in a particular order, other method embodiments may be performed in any logical order.

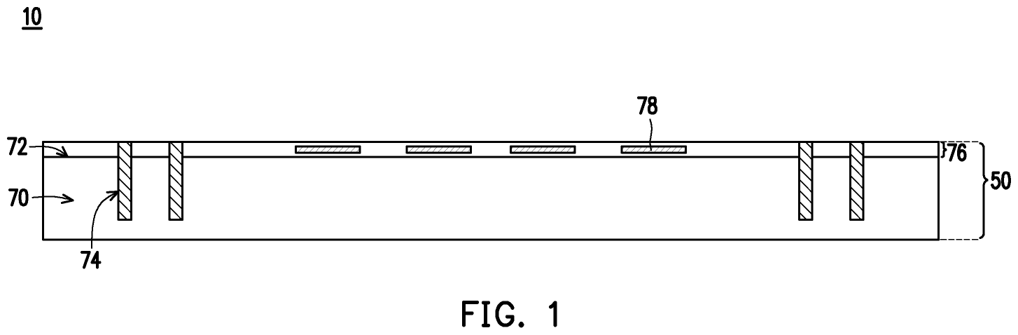

FIGS. 1 through 6 illustrate cross-sectional views of intermediate steps during a process for forming an integrated chip package 10, in accordance with some embodiments. FIG. 1 illustrates a package component 50. The package component 50 may be an interposer that comprises a substrate 70. The substrate 70 can be a wafer. The substrate 70 may comprise a bulk semiconductor substrate, SOI substrate, multi-layered semiconductor substrate, or the like. The semiconductor material of the substrate 70 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 70 may be doped or undoped. In an embodiment in which the package component 50 is an interposer, the package component 50 will not include active devices therein, although the substrate 70 may include passive devices formed in and/or on a first surface 72 of the substrate 70. In an embodiment, the package component 50 may be an active die (e.g., a bottom die) that may comprise devices, such as transistors, capacitors, resistors, diodes, and the like, that may be formed in and/or on the first surface 72, which may also be referred to as an active surface, of the substrate 70. In an embodiment, the package component 50 may be a micro-electro-mechanical-system (MEMS) die. In other embodiments, the package component 50 may be an organic interposer that comprises polymer-based layers with metal traces and vias embedded in the polymer-based layers. The polymer-based layers may comprise a polymer material such as polyimide (PI), or the like. The metal traces and vias may comprise a conductive material such as copper, aluminum, or the like.

Still referring to FIG. 1, the package component 50 may comprise a redistribution structure 76 that is formed over the first surface 72 of the substrate 70. The redistribution structure 76 may comprise insulating layers and metallization patterns 78 within each of the insulating layers. In some embodiments, the redistribution structure 76 may have any number of insulating layers or metallization patterns 78. The side of the package component 50 having the exposed top surface of the redistribution structure 76 may be referred to subsequently as the front side of the package component 50. The side of the package component 50 having the exposed surface of the substrate 70 may be referred to subsequently as the back side of the package component 50.

Each of the insulating layers may comprise, for example, a dielectric material such as silicon oxide (SiOₓ, where x>0), silicon nitride (SiNₓ, where x>0), silicon oxynitride (SiOₓN_{y}, where x>0 and y>0), or the like. In other embodiments, each of the insulating layers may comprise a low-K dielectric material, such as phosphosilicate glass (PSG), borophosphosilicate glass (BPSG), fluorosilicate glass (FSG), SiOₓC_{y}, Spin-On-Glass, Spin-On-Polymers, silicon carbon material, compounds thereof, composites thereof, combinations thereof, or the like. The insulating layers may be formed by any suitable method known in the art, such as spinning, chemical vapor deposition (CVD), plasma-enhanced CVD (PECVD), high-density plasma chemical vapor deposition (HDP-CVD), or the like. A metallization pattern 78 may then be formed in the insulating layer, for example, by using photolithography techniques to deposit and pattern a photoresist material on the insulating layer to expose portions of the insulating layer that are to become the metallization pattern 78. An etch process, such as an anisotropic dry etch process, may be used to create recesses and/or openings in the insulating layer corresponding to the exposed portions of the insulating layer. The recesses and/or openings may be lined with a diffusion barrier layer and filled with a conductive material. The diffusion barrier layer may comprise one or more layers of tantalum nitride, tantalum, titanium nitride, titanium, cobalt tungsten, the like, or a combination thereof, deposited by atomic layer deposition (ALD), or the like. The conductive material of the metallization patterns 78 may comprise copper, aluminum, tungsten, silver, and combinations thereof, or the like, deposited by CVD, physical vapor deposition (PVD), or the like. Any excessive diffusion barrier layer and/or conductive material on the insulating layer may be removed, such as by using a chemical mechanical polish (CMP).

The package component 50 may comprise through-vias (TVs) 74 that are formed to extend through the redistribution structure 76 and partially through the substrate 70 (e.g., from the first surface 72 of substrate 70 into substrate 70). The TVs 74 are also sometimes referred to as through-substrate vias or through-silicon vias when substrate 70 is a silicon substrate. The TVs 74 may be formed after forming the redistribution structure 76. In some embodiments, the TVs 74 may be formed by forming recesses in the redistribution structure 76 and the substrate 70 by, for example, etching, milling, laser techniques, a combination thereof, and/or the like. A thin dielectric material may be formed in the recesses, such as by using an oxidation technique (e.g., to oxidize silicon surfaces of the substrate 70 in the recesses). A thin barrier layer may be conformally deposited over the front side of the package component 50 and in the openings, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the package component 50 by, for example, CMP. Thus, the TVs 74 may comprise a conductive material and a thin barrier layer between the conductive material and the substrate 70, and between the conductive material and redistribution structure 76.

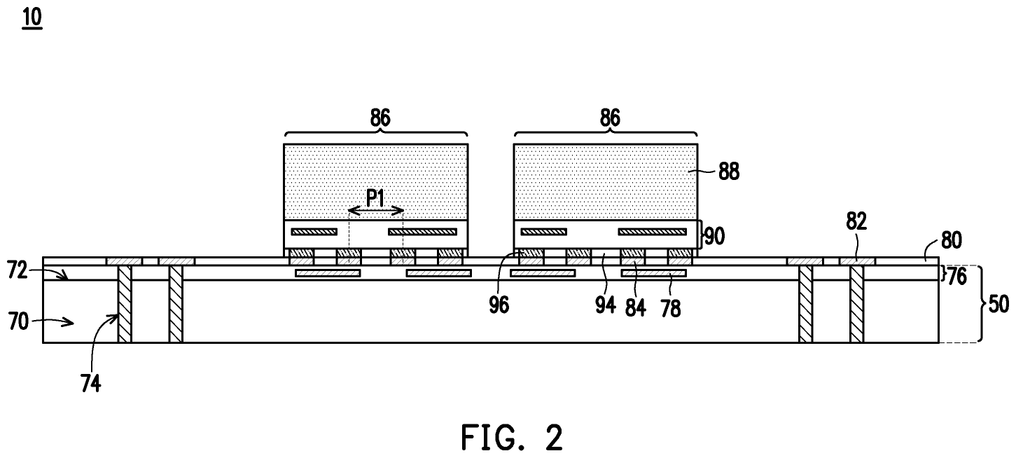

FIG. 2 illustrates the bonding of semiconductor dies 86 to the package component 50. Even though FIG. 2 illustrates two semiconductor dies 86, any number of semiconductor dies 86 may be bonded to the package component 50. Each of the semiconductor dies 86 may be a logic die (e.g., application processor (AP), central processing unit (CPU), graphics processing unit (GPU), microcontroller, etc.), a memory die (e.g., dynamic random access memory (DRAM) die, hybrid memory cube (HBC), a static random access memory (SRAM) die, a wide input/output (wideIO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like. Each semiconductor die 86 may also be a System-on-Chip (SoC) die, or the like.

Each semiconductor die 86 may include a substrate 88 (e.g., a semiconductor substrate), an interconnect structure 90 disposed on the substrate 88, a bonding layer 94 disposed on the interconnect structure 90, and bonding pads 96 disposed in the bonding layer 94 and exposed at a front surface of the semiconductor die 86. The side of the semiconductor die comprising the bonding pads 96 and the bonding layer 94 may also be referred to subsequently as the front side of the semiconductor die 86.

The substrate 88 of the semiconductor die 86 may comprise crystalline silicon. The substrate 88 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 88 may comprise an active layer of a semiconductor-on-insulator (SOI) substrate. The substrate 88 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Active and/or passive devices, such as transistors, diodes, capacitors, resistors, etc., may be formed in and/or on the substrate 88. The devices may be interconnected by the interconnect structure 90. The interconnect structure 90 electrically connects the devices on the substrate 88 to form one or more integrated circuits. The interconnect structure 90 may include one or more dielectric layers (for example, one or more interlayer dielectric (ILD) layers, intermetal dielectric (IMD) layers, or the like) and interconnect wirings or metallization patterns embedded in the one or more dielectric layers. The material of the one or more dielectric layers may include silicon oxide (SiOₓ, where x>0), silicon nitride (SiNₓ, where x>0), silicon oxynitride (SiOₓN_{y}, where x>0 and y>0), or other suitable dielectric material. The interconnect wirings may include metallic wirings. For example, the interconnect wirings include copper wirings, copper pads, aluminum pads or combinations thereof that are formed by one or more single damascene processes, dual damascene processes, or the like. The side of the semiconductor die 86 comprising an exposed back side surface of the substrate 88 may also be referred to subsequently as the back side of the semiconductor die 86.

The bonding layer 94 may comprise a dielectric layer. Bonding pads 96 are embedded in the bonding layer 94, and the bonding pads 96 allow connections to be made to the interconnect structure 90 and the devices on the substrate 88. The material of the bonding layer 94 may be silicon oxide (SiOₓ, where x>0), silicon nitride (SiNₓ, where x>0), silicon oxynitride (SiOₓN_{y}, where x>0 and y>0), tetraethyl orthosilicate (TEOS), or other suitable dielectric material, and the bonding pads 96 may comprise conductive pads (e.g., copper pads), conductive vias (e.g., copper vias), or combinations thereof. The bonding layer 94 may be formed by depositing a dielectric material over the interconnect structure 90 using a chemical vapor deposition (CVD) process (e.g., a plasma enhanced CVD process or other suitable process); patterning the dielectric material to form the bonding layer 94 including openings or through holes; and filling conductive material in the openings or through holes defined in the bonding layer 94 to form the bonding pads 96 embedded in the bonding layer 94.

Referring further to FIG. 2, a bonding layer 80 and bonding pads 84 are formed over the front side of the package component 50, such as over the redistribution structure 76. The bonding layer 80 and the bonding pads 84 may be formed using similar materials and similar processes as those described above for the formation of the bonding layer 94 and the bonding pads 96, respectively. The bonding pads 84 allow electrical connections to be made to the metallization patterns 78 of the redistribution structure 76. The bonding pads 96 and the bonding pads 84 may have a first pitch P1 that is less than 9 μm, wherein the first pitch P1 is a distance from the center of a bonding pad 96 or a bonding pad 84 to the center of an adjacent bonding pad 96 or bonding pad 84, respectively. During the formation of the bonding pads 84, conductive pads 82 are also formed in the bonding layer 80 using similar materials and similar processes as those described previously for the formation of the bonding pads 84 and the bonding pads 96. The conductive pads 82 may overlap respective ones of the TVs 74. In an embodiment, the conductive pads 82 may also overlap portions of the redistribution structure 76. In an embodiment, a width of each conductive pad 82 is smaller than a width of each TV 74. In an embodiment, a width of each conductive pad 82 is greater than a width of each TV 74. The conductive pads 82 may be formed to be in physical contact with and allow electrical connections to be made to the TVs 74.

After the formation of the bonding layer 80, the bonding pads 84, and the conductive pads 82, the semiconductor dies 86 are bonded to the package component 50, for example, in a hybrid bonding configuration. The semiconductor dies 86 may be disposed face down such that front sides of the semiconductor dies 86 face the redistribution structure 76 of the package component 50, and back sides of the semiconductor dies 86 face away from the package component 50 (e.g., in a face-to-face (F2F) configuration. The semiconductor dies 86 are bonded to the bonding layer 80 on the front side of the package component 50 and the bonding pads 84 in the bonding layer 80. For example, the bonding layer 94 of the semiconductor dies 86 may be directly bonded to the bonding layer 80 on the package component 50, and bonding pads 96 of the semiconductor dies 86 may be directly bonded to the bonding pads 84 on the package component 50. In an embodiment, the bond between the bonding layer 94 and the bonding layer 80 may be an oxide-to-oxide bond, or the like. The hybrid bonding process further directly bonds the bonding pads 96 of the semiconductor dies 86 to the bonding pads 84 on the package component 50 through direct metal-to-metal bonding. Thus, electrical connection between the semiconductor dies 86 and the package component 50 is provided by the physical connection of the bonding pads 96 to the bonding pads 84.

As an example, the hybrid bonding process starts with aligning the semiconductor dies 86 with the package component 50, for example, by applying a surface treatment to one or more of the bonding layer 94 or the bonding layer 80. The surface treatment may include a plasma treatment. The plasma treatment may be performed in a vacuum environment. After the plasma treatment, the surface treatment may further include a cleaning process (e.g., a rinse with deionized water, or the like) that may be applied to one or more of the bonding layer 94 or the bonding layer 80. The hybrid bonding process may then proceed to aligning the bonding pads 96 to the bonding pads 84. Next, the hybrid bonding includes a pre-bonding step, during which the semiconductor dies 86 are put in contact with the package component 50. The pre-bonding may be performed at room temperature (e.g., between about 21° C. and about 25° C.). The hybrid bonding process continues with performing an anneal, for example, at a temperature between about 150° C. and about 400° C. for a duration between about 0.5 hours and about 3 hours, so that the metal in bonding pads 96 (e.g., copper) and the metal of the bonding pads 84 (e.g., copper) inter-diffuses to each other, and hence the direct metal-to-metal bonding is formed.

In other embodiments, the bonding layer 94 and the bonding pads 96 may be formed on the back sides (e.g., on the exposed surfaces of the substrates 88) of the semiconductor dies 86 instead of the front sides (e.g., on the interconnect structures 90) of the semiconductor dies 86. The semiconductor dies 86 may then be bonded to the package component 50, for example, in a hybrid bonding configuration using similar processes as were described above to directly bond the bonding layer 94 of the semiconductor dies 86 to the bonding layer 80 of the package component 50, and to directly bond the bonding pads 96 of the semiconductor dies 86 to the bonding pads 84 of the package component 50. After this bonding, the semiconductor dies 86 may be disposed face up such that the front sides of the semiconductor dies 86 face away from the package component 50, and the back sides of the semiconductor dies 86 face the redistribution structure 76 of the package component 50 (e.g., in a face-to-back (F2B) configuration).

Referring further to FIG. 2, a thinning process is performed on the exposed surface of the substrate 70 on the back side of the package component 50 in order to expose the TVs 74. The thinning process may include an etching process, a grinding process, the like, or a combination thereof. The thinning process may be performed before or after the bonding of the semiconductor dies 86 to the package component 50.

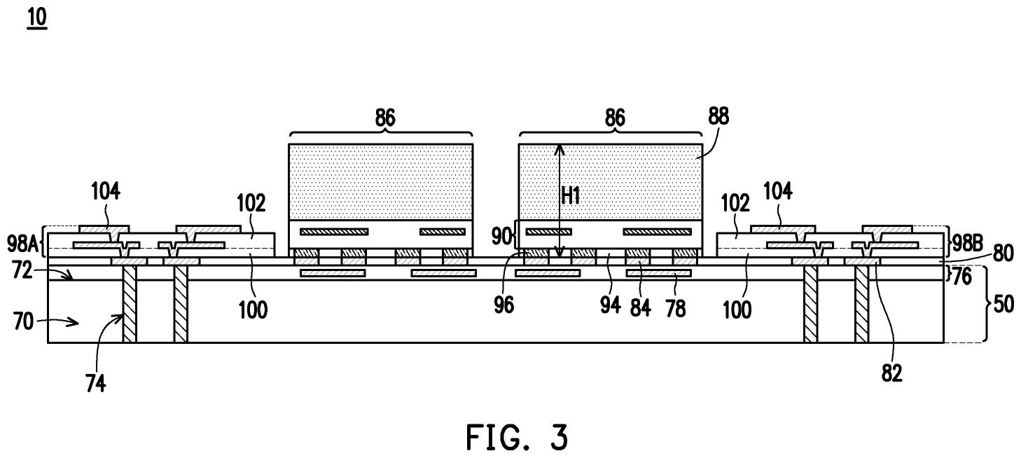

FIG. 3 illustrates the formation of a redistribution structure 98 over the package component 50, the redistribution structure 76, the bonding layer 80, and the conductive pads 82. Specifically, the redistribution structure 98 comprises a first portion of the redistribution structure 98A and a second portion of the redistribution structure 98B that are disposed adjacent to the semiconductor dies 86. In an embodiment, the semiconductor dies 86 may be disposed between the first portion of the redistribution structure 98A and the second portion of the redistribution structure 98B.

Each of the first portion of the redistribution structure 98A and the second portion of the redistribution structure 98B may comprise insulating layers (e.g., insulating layer 100, and insulating layer 102), and metallization patterns within each of the insulating layers. In some embodiments, each of the first portion of the redistribution structure 98A and the second portion of the redistribution structure 98B may have any number of insulating layers or metallization patterns.

In an embodiment in which a height H1 of each semiconductor die 86 is less than 30 μm, each of the insulating layers (e.g., the insulating layers 100 and 102) may comprise, for example, a dielectric material such as silicon oxide, silicon nitride, or the like, that is formed conformally over the semiconductor dies 86, the bonding layer 80, and the conductive pads 82 using any suitable method known in the art, such as chemical vapor deposition (CVD), atomic layer deposition (ALD), or the like. In other embodiments, each insulating layer may comprise an ultra low viscosity polyimide (PI) that is formed over the bonding layer 80 and the conductive pads 82 using a spinning process, a spray coating process (e.g., by using a nozzle), or the like, wherein due to low wetting properties of the ultra low viscosity polyimide (PI), the insulating layer does not form a uniform film (i.e., is not formed) on top surfaces and top portions of the sidewalls of the semiconductor dies 86, and is instead only formed on the bonding layer 80 and the conductive pads 82, as well as bottom portions of the sidewalls of the semiconductor dies 86. A metallization pattern may then be formed in the insulating layer, for example, by using photolithography techniques to deposit and pattern a photoresist material over the semiconductor dies 86 and the insulating layer to expose portions of the insulating layer that are to become the metallization pattern. An etch process, such as an anisotropic dry etch process, may be used to create recesses and/or openings in the insulating layer corresponding to the exposed portions of the insulating layer. The recesses and/or openings may be lined with a diffusion barrier layer and filled with a conductive material. The diffusion barrier layer may comprise one or more layers of tantalum nitride, tantalum, titanium nitride, titanium, cobalt tungsten, the like, or a combination thereof, deposited by atomic layer deposition (ALD), or the like. The conductive material of the metallization patterns may comprise copper, aluminum, tungsten, silver, and combinations thereof, or the like, deposited by CVD, physical vapor deposition (PVD), or the like. After the formation of the insulating layer and the metallization pattern in the insulating layer, the diffusion barrier layer, the conductive material, the photoresist material, and portions of the insulating layer (if present) over top surfaces and sidewalls of the semiconductor dies 86 may be removed, such as by using any suitable combination of processes such as chemical mechanical polish (CMP), etching, ashing, chemical stripping, or the like, to leave portions of the insulating layer and the metallization pattern in the insulating layer disposed adjacent to the semiconductor dies 86. In addition, any excess diffusion barrier layer, conductive material, and the photoresist material over the portions of the insulating layer and the metallization pattern in the insulating layer (e.g., disposed adjacent to the semiconductor dies 86) may be removed through any suitable combination of processes such as chemical mechanical polish (CMP), etching, ashing, chemical stripping, or the like. Any number of insulating layers and corresponding metallization patterns may be formed using similar processes and materials as described above to form the first portion of the redistribution structure 98A and the second portion of the redistribution structure 98B that are disposed adjacent to the semiconductor dies 86.

Referring further to FIG. 3, the first portion of the redistribution structure 98A and the second portion of the redistribution structure 98B may also comprise under bump metallurgies (UBMs) 104 that are formed over a topmost insulating layer (e.g., the insulating layer 102) for external connection to each of the first portion of the redistribution structure 98A and the second portion of the redistribution structure 98B. The UBMs 104 may comprise conductive pads, conductive bumps, or the like, that extend along the major surface of the topmost insulating layer (e.g., the insulating layer 102), and are in physical and electrical contact with a metallization pattern in the topmost insulating layer (e.g., the insulating layer 102). The TVs 74 are also electrically connected to the UBMs 104 through the redistribution structure 98. The UBMs 104 may be formed of the same material as the metallization patterns of the redistribution structure 98. In some embodiments, the UBMs 104 may have a different size than the metallization patterns of the redistribution structure 98.

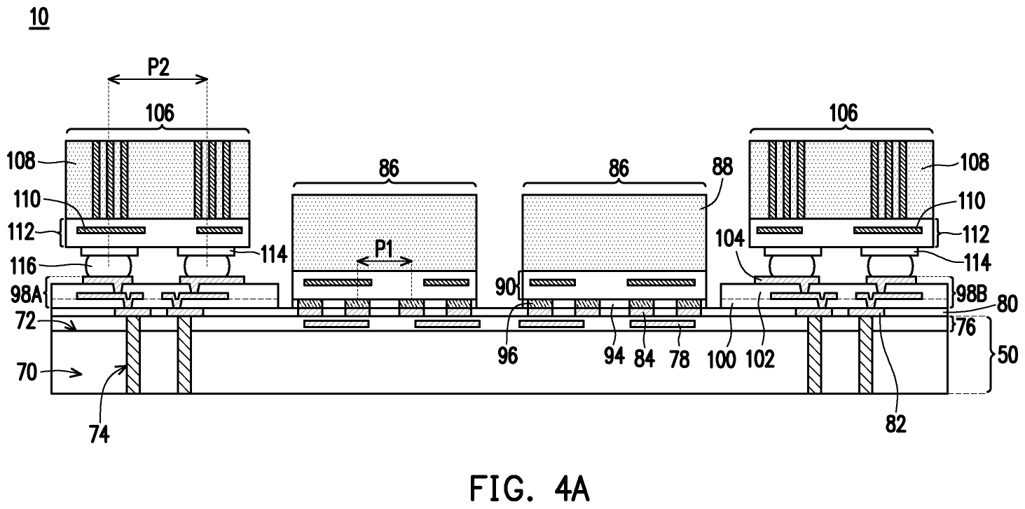

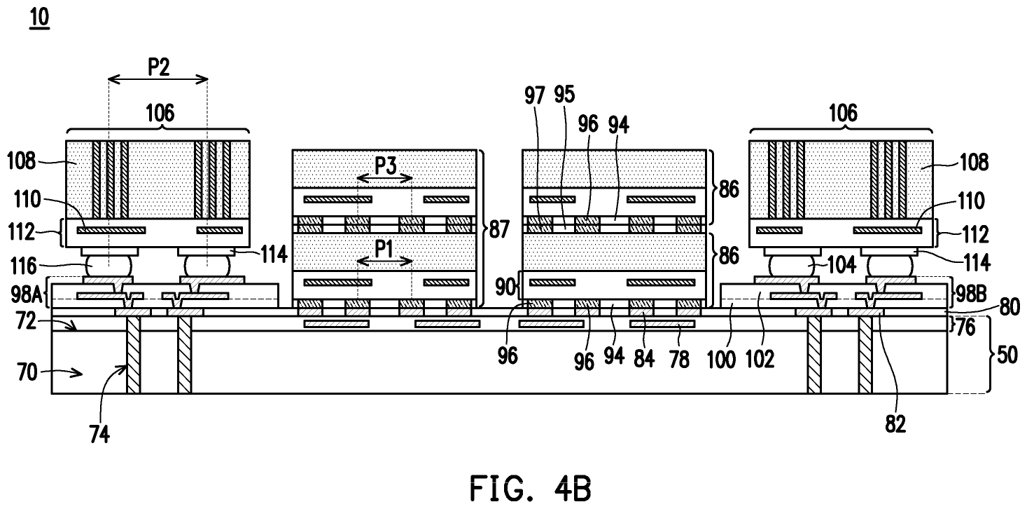

FIG. 4A illustrates the coupling of semiconductor dies 106 to the package component 50. Even though FIG. 4A illustrates two semiconductor dies 106, any number of semiconductor dies 106 may be coupled to the package component 50. The semiconductor dies 106 may be formed through similar processing as described above in reference to the semiconductor dies 86. In some embodiments, the semiconductor dies 106 may be memory dies, such as a stack of memory dies (e.g., DRAM dies, SRAM dies, High-Bandwidth Memory (HBM) dies, Hybrid Memory Cubes (HMC) dies, or the like). In the stack of memory dies embodiments, a semiconductor die 106 can include both memory dies and a memory controller, such as, for example, a stack of four or eight memory dies with a memory controller. Also, in some embodiments, the semiconductor dies 106 may be different sizes (e.g., different heights and/or surface areas), and in other embodiments, the semiconductor dies 106 may be the same size (e.g., same heights and/or surface areas). In some embodiments, each semiconductor die 106 may comprise multiple DRAM dies that are vertically stacked on top of each other. The stacking of these dies allows for increased memory density without significantly increasing the physical footprint of the memory module. Each individual DRAM die in the stack may be interconnected using through-silicon vias (TSVs), micro bumps, or the like.

In some embodiments, the semiconductor dies 106 may be similar heights to those of the semiconductor dies 86 or in some embodiments, the semiconductor dies 86 and 106 may be of different heights.

The semiconductor dies 106 include a main body 108, an interconnect structure 112, and die connectors 114. The main body 108 of the semiconductor dies 106 may comprise any number of dies, substrates, transistors, active devices, passive devices, or the like. In an embodiment, the main body 108 may include a bulk semiconductor substrate, semiconductor-on-insulator (SOI) substrate, multi-layered semiconductor substrate, or the like. The semiconductor material of the main body 108 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The main body 108 may be doped or undoped. Devices, such as transistors, capacitors, resistors, diodes, and the like, may be formed in and/or on an active surface.

An interconnect structure 112 comprising one or more dielectric layer(s) and respective metallization pattern(s) is formed on the active surface. The metallization pattern(s) in the dielectric layer(s) may route electrical signals between the devices, such as by using vias and/or traces, and may also contain various electrical devices, such as capacitors, resistors, inductors, or the like. The various devices and metallization patterns may be interconnected to perform one or more functions. The functions may include memory structures, processing structures, sensors, amplifiers, power distribution, input/output circuitry, or the like. Additionally, die connectors 114, such as conductive pads, conductive pillars, or the like, that comprise a metal such as copper, or the like, are formed in and/or on the interconnect structure 112 to provide an external electrical connection to the circuitry and devices. In some embodiments, the die connectors 114 may protrude from the interconnect structure 112 and may be utilized when bonding the semiconductor dies 106 to other structures. One of ordinary skill in the art will appreciate that the above examples are provided for illustrative purposes. Other circuitry may be used as appropriate for a given application.

More particularly, an IMD layer may be formed in the interconnect structure 112. The IMD layer may be formed, for example, of a low-K dielectric material, such as PSG, BPSG, FSG, SiOₓC_{y}, Spin-On-Glass, Spin-On-Polymers, silicon carbon material, compounds thereof, composites thereof, combinations thereof, or the like, by any suitable method known in the art, such as spinning, CVD, PECVD, HDP-CVD, or the like. A metallization pattern may be formed in the IMD layer, for example, by using photolithography techniques to deposit and pattern a photoresist material on the IMD layer to expose portions of the IMD layer that are to become the metallization pattern. An etch process, such as an anisotropic dry etch process, may be used to create recesses and/or openings in the IMD layer corresponding to the exposed portions of the IMD layer. The recesses and/or openings may be lined with a diffusion barrier layer and filled with a conductive material. The diffusion barrier layer may comprise one or more layers of tantalum nitride, tantalum, titanium nitride, titanium, cobalt tungsten, the like, or a combination thereof, deposited by ALD, or the like. The conductive material of the metallization patterns may comprise copper, aluminum, tungsten, silver, and combinations thereof, or the like, deposited by CVD, PVD, or the like. Any excessive diffusion barrier layer and/or conductive material on the IMD layer may be removed, such as by using a CMP.

To couple the semiconductor dies 106 to the package component 50, conductive connectors 116 are formed on respective ones of the exposed UBMs 104. The conductive connectors 116 are electrically coupled to the first portion of the redistribution structure 98A and the second portion of the redistribution structure 98B through the UBMs 104. The conductive connectors 116 may comprise micro bumps, solder balls, or the like. The conductive connectors 116 may comprise a conductive material such as lead-free solder, copper, aluminum, gold, nickel, silver, palladium, tin, the like, or a combination thereof. In some embodiments, the conductive connectors 116 are formed by initially forming a layer of solder through evaporation, electroplating, printing, solder transfer, ball placement, or the like. Once a layer of solder has been formed on the structure, a reflow may be performed in order to shape the material into the desired bump shapes.

After the formation of the conductive connectors 116, the semiconductor dies 106 are placed on the conductive connectors 116, making electrical connection between each semiconductor die 106 and either the first portion of the redistribution structure 98A or the second portion of the redistribution structure 98B through the UBMs 104. The semiconductor dies 106 may be placed on the conductive connectors 116 using a placement process such as a pick-and-place process, or the like. Each semiconductor die 106 may be placed such that the die connectors 114 are aligned with corresponding connectors of the conductive connectors 116 on the UBMs 104. Once in physical contact, a reflow process may be utilized to bond the conductive connectors 116 on the redistribution structure 98A and the second portion of the redistribution structure 98B to the semiconductor dies 106. In some embodiments, conductive connectors 116 are formed on the die connectors 114 of the semiconductor dies 106 instead of or in addition to the conductive connectors 116 formed on the UBMs 104. The conductive connectors 116 may have a second pitch P2 that is greater than the first pitch P1, wherein the second pitch P2 is a distance from the center of a conductive connector 116 to the center of an adjacent conductive connector 116, respectively. In an embodiment, the second pitch P2 may be greater than 30 μm.

Advantages can be achieved by forming the integrated chip package 10, wherein forming the integrated chip package 10 comprises bonding each semiconductor die 86 to the package component 50 using a hybrid bonding configuration, wherein the bonding pads 96 of the semiconductor dies 86 are bonded to and electrically connected to the bonding pads 84 on the package component 50 through direct metal-to-metal bonding. The hybrid bonding configuration also comprises directly bonding the bonding layer 94 of each semiconductor die 86 to the bonding layer 80 on the package component 50 using a dielectric-to-dielectric bond. Forming the integrated chip package 10 further comprises coupling and electrically connecting the semiconductor dies 106 to the package component 50 using the conductive connectors 116, such as micro bumps, or the like. The bonding pads 96 and the bonding pads 84 may have the first pitch P1 that is less than 9 μm. The conductive connectors 116 may have the second pitch P2 (e.g., greater than 30 μm) that is greater than the first pitch P1. These advantages include allow the bonding of semiconductor dies having different interconnection bandwidth requirements to the package component 50. For example, the semiconductor die 86 may be a graphics processing unit (GPU), central processing unit (CPU), or the like that requires a high input/output signal transfer capability. Because the first pitch P1 is less than 9 μm, a greater number of the bonding pads 96 and the bonding pads 84 that bond each semiconductor die 86 to the package component 50 can be utilized per unit area (due to the hybrid bonding configuration) of the semiconductor die 86 and the package component 50, which allows for greater interconnection bandwidths and faster signal transmission between the semiconductor die 86 and the package component 50. As a result of the greater number of the bonding pads 96 and the bonding pads 84 being utilized per unit area of the semiconductor die 86 and the package component 50, a size of the integrated chip package 10 can be reduced as compared to if other types of conductive connectors (e.g., solder bumps) that have a greater pitch than the first pitch P1 are used to bond the semiconductor die 86 to the package component 50. The semiconductor die 106 may be a memory die, or the like, that may not require as high a signal transfer capability. It then becomes sufficient to use the conductive connectors 116 that have the second pitch P2 (e.g., greater than 30 μm) to couple the semiconductor dies 106 to the package component 50, while still fulfilling interconnection bandwidth requirements. In addition, the use of the conductive connectors 116 to couple the semiconductor dies 106 to the package component 50 results in lower manufacturing costs due to the larger second pitch P2, and also results in better electrical connection between the semiconductor dies 106 and the package component 50, which improves device yield and reliability. Therefore, forming the integrated chip package 10 by concurrently using the bonding pads 96/84 and the bonding layers 94/80 to bond the semiconductor dies 86 (e.g., having high interconnection bandwidth requirements) to the package component 50, and using the conductive connectors 116 to couple the semiconductor dies 106 (e.g., having lower interconnection bandwidth requirements than the semiconductor dies 86) to the package component 50 may allow for the overall reduction of the size of the integrated chip package 10, a reduction in manufacturing costs, and an improved device yield and reliability of the integrated chip package 10.

FIG. 4B illustrates the integrated chip package 10 in accordance with an alternative embodiment. Unless specified otherwise, like reference numerals in this embodiment (and subsequently discussed embodiments) represent like components in the embodiment shown in FIGS. 1 through 4A formed by like processes. Accordingly, the process steps and applicable materials may not be repeated herein. The embodiment of FIG. 4B is different from the embodiment of FIG. 4A in that in the embodiment of FIG. 4B, after the semiconductor dies 86 (e.g., also referred to as first semiconductor dies 86) are bonded to the package component 50 as shown previously in FIG. 2, an additional semiconductor die 86 (e.g., also referred to as a second semiconductor die 86) is bonded to a top surface of each of the first semiconductor dies 86. In this way, semiconductor dies 86 are stacked directly on top of each other to form multi-chip stacks 87. After the formation of the multi-chip stacks 87, the redistribution structure 98 is formed over the package component 50 as described previously in FIG. 3, and the semiconductor dies 106 are coupled to the package component 50 using the conductive connectors 116 as described previously in FIG. 4A.

As shown in FIG. 4B, each of the first semiconductor dies 86 that are bonded to the package component 50 may comprise a bonding layer 95 disposed on the back side of each of the first semiconductor dies 86, and bonding pads 97 disposed in the bonding layer 95. The bonding layer 95 and the bonding pads 97 may be formed using similar processes and materials as were previously described in FIG. 2 for the formation of the bonding layer 94 and the bonding pads 96, respectively.

After the first semiconductor dies 86 are bonded to the package component 50 as shown previously in FIG. 2, the second semiconductor dies 86 are bonded to top surfaces of respective ones of the first semiconductor dies 86, for example, in a hybrid bonding configuration. The second semiconductor dies 86 may be disposed face down such that front sides of the second semiconductor dies 86 face the back sides of the first semiconductor dies 86. The second semiconductor dies 86 are bonded to the bonding layer 95 and the bonding pads 97 in the bonding layer 95 of respective ones of the first semiconductor dies 86. For example, the bonding layer 94 of each second semiconductor die 86 may be directly bonded to the bonding layer 95 of a respective first semiconductor die 86 in a similar manner and using similar processes as were described previously in FIG. 2 for the bonding of the bonding layer 94 of each semiconductor die 86 to the bonding layer 80 on the package component 50. In addition, the bonding pads 96 of each second semiconductor die 86 may be directly bonded to the bonding pads 97 of a respective first semiconductor die 86 in a similar manner and using similar processes as were described previously in FIG. 2 for the bonding of the bonding pads 96 of the semiconductor dies 86 to the bonding pads 84 on the package component 50.

After the bonding of the second semiconductor dies 86 to respective ones of the first semiconductor dies 86 to form the multi-chip stacks 87, the redistribution structure 98 is formed over the package component 50 as described previously in FIG. 3, and the semiconductor dies 106 are coupled to the package component 50 using the conductive connectors 116 as described previously in FIG. 4A. In an embodiment, the second semiconductor dies 86 may be electrically connected to the redistribution structure 76 through, for example, the bonding pads 97, and circuitry and/or through vias disposed within the first semiconductor dies 86. In an embodiment, after the second semiconductor dies 86 are bonded to respective ones of the first semiconductor dies 86, and after the semiconductor dies 106 are coupled to the package component 50 using the conductive connectors 116, top surfaces of the second semiconductor dies 86 may be lower than top surfaces of the semiconductor dies 106. In an embodiment, the bonding pads 97 of each first semiconductor die 86 may have a third pitch P3 that is less than 9 μm, wherein the third pitch P3 is a distance from the center of a bonding pad 97 to the center of an adjacent bonding pad 97.

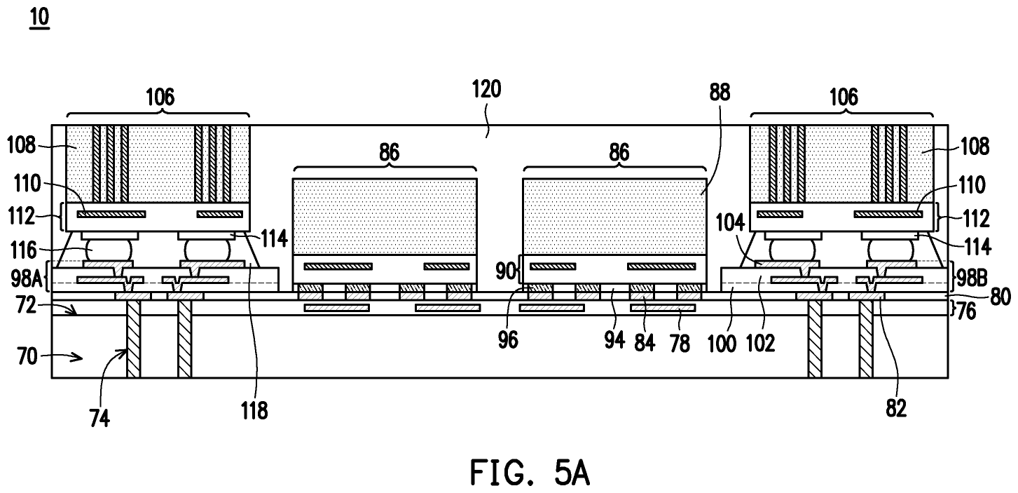

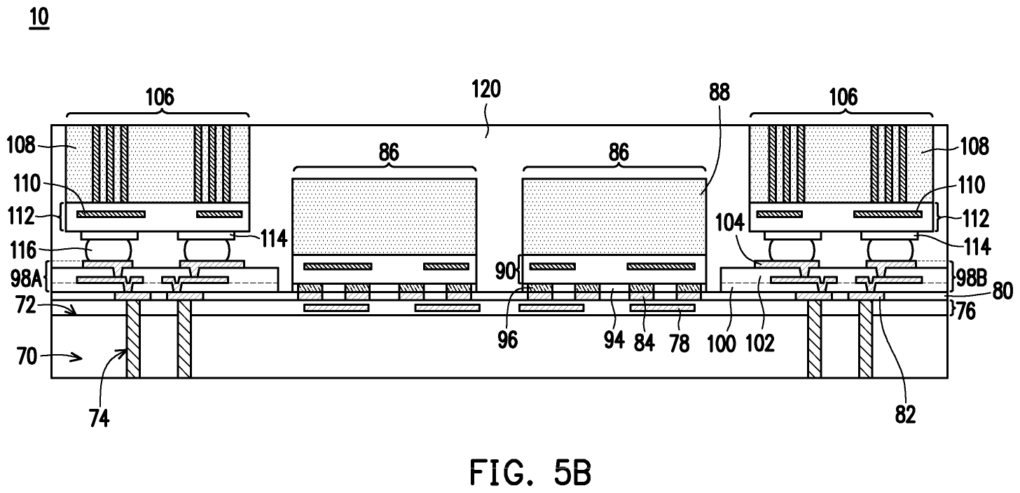

In FIG. 5A, an underfill 118 may be formed between the first portion of the redistribution structure 98A and each semiconductor die 106 disposed above the first portion of the redistribution structure 98A, and between the second portion of the redistribution structure 98B and each semiconductor die 106 disposed above the second portion of the redistribution structure 98B. The underfill 118 surrounds the conductive connectors 116. In addition, the underfill 118 may surround portions of the UBMs 104 and the die connectors 114. The underfill 118 may be formed by a capillary flow process after the coupling of the semiconductor dies 106 to the first portion and the second portions of the redistribution structure 98A/B or may be formed by a suitable deposition method before the semiconductor dies 106 are coupled to the first and second portions of the redistribution structure 98A/B. The material of the underfill 118 may comprise a polymer, epoxy, molding underfill, or the like.

Referring further to FIG. 5A, after forming the underfill 118, an encapsulant 120 is formed on the various components of the integrated chip package 10. The encapsulant 120 may be a molding compound, epoxy, or the like, and may be applied by compression molding, transfer molding, or the like. A curing step is performed to cure the encapsulant 120, such as a thermal curing, an Ultra-Violet (UV) curing, or the like. In some embodiments, each of the semiconductor dies 86 and the semiconductor dies 106 are buried in the encapsulant 120, and after the curing of the encapsulant 120, a planarization step, such as a grinding, may be performed to remove excess portions of the encapsulant 120, which excess portions are over top surfaces of the semiconductor dies 106. Accordingly, in some embodiments, after the planarization step, top surfaces of the semiconductor dies 106 are exposed, and are level with a top surface of the encapsulant 120. In an embodiment, top surfaces of the semiconductor dies 86 are below the top surface of the encapsulant 120. In some embodiments, the top surfaces of the semiconductor dies 86 and the semiconductor dies 106 may still be covered by the encapsulant 120 after the planarization step.

FIG. 5B illustrates the integrated chip package 10 in accordance with an alternative embodiment. Unless specified otherwise, like reference numerals in this embodiment (and subsequently discussed embodiments) represent like components in the embodiment shown in FIGS. 1 through 5A formed by like processes. Accordingly, the process steps and applicable materials may not be repeated herein. The embodiment of FIG. 5B is different from the embodiment of FIG. 5A in that in the embodiment of FIG. 5B, the formation of the underfill 118 is omitted. The encapsulant 120 is formed on the various components of the integrated chip package 10. In an embodiment, the encapsulant 120 is able to also function as an underfill and fill the space between the first portion of the redistribution structure 98A and each semiconductor die 106 disposed above the first portion of the redistribution structure 98A, and fill the space between the second portion of the redistribution structure 98B and each semiconductor die 106 disposed above the second portion of the redistribution structure 98B. The encapsulant 120 also surrounds the conductive connectors 116. In addition, the encapsulant 120 may surround portions of the UBMs 104 and the die connectors 114.

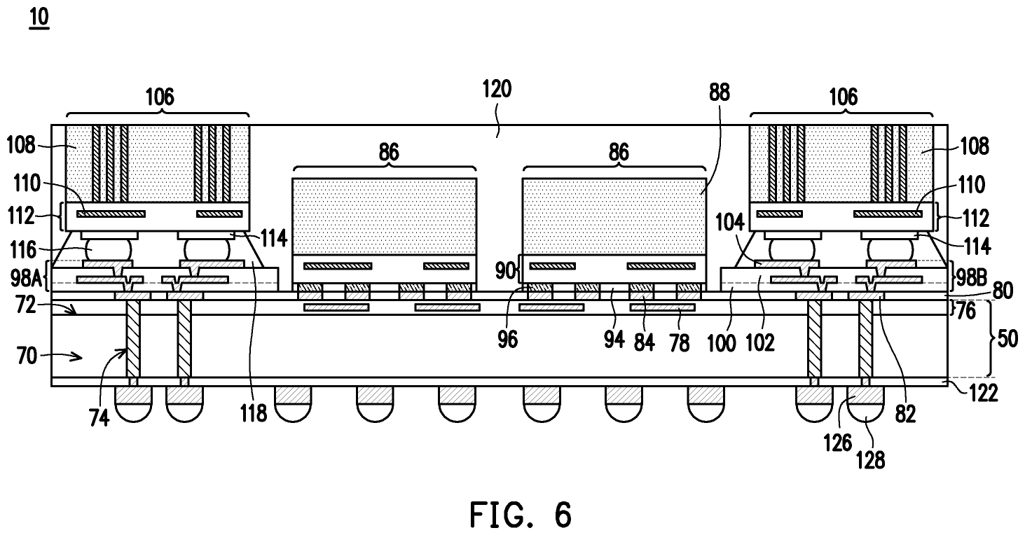

In FIG. 6, a dielectric layer 122 is formed on the back side of the package component 50, such as on the substrate 70 and the exposed TVs 74. The dielectric layer 122 may comprise silicon oxide, silicon nitride, or the like, that is formed using any suitable method known in the art, such as chemical vapor deposition (CVD), atomic layer deposition (ALD), or the like. In an embodiment, the dielectric layer may comprise a polymer such as polybenzoxazole (PBO), a polymide (PI), a polymide derivative, or the like, that is formed using a spin-coating process, or the like. FIG. 6 additionally illustrates a patterning of the dielectric layer 122 in order to form openings that expose the TVs 74. In an embodiment, the dielectric layer 122 may be patterned to form the openings that expose the TVs 74 by initially applying a photoresist (not individually illustrated in FIG. 6) to the dielectric layer 122 and then exposing the photoresist to a patterned energy source (e.g., a patterned light source) so as to induce a chemical reaction, thereby inducing a physical change in those portions of the photoresist exposed to the patterned light source. A developer is then applied to the exposed photoresist to take advantage of the physical changes and selectively remove either the exposed portion of the photoresist or the unexposed portion of the photoresist, depending upon the desired pattern, and the underlying exposed portion of the dielectric layer 122 are removed with, e.g., a dry etch process. However, any other suitable method for patterning the dielectric layer 122 to form the openings may be utilized.

After the formation and the patterning of the dielectric layer 122, UBMs 126 are formed for external connection to the TVs 74. The UBMs 126 may have bump portions on and extending along the major surface of the dielectric layer 122, and have via portions extending through the dielectric layer 122 to physically and electrically couple the TVs 74 of the package component 50. As a result, the UBMs 126 are electrically coupled to the redistribution structure 76, and the redistribution structure 98. The UB Ms 126 may be formed of a conductive material such as copper, aluminum, tungsten, silver, and combinations thereof, or the like, deposited by CVD, physical vapor deposition (PVD), or the like.

Referring further to FIG. 6, conductive connectors 128 are formed on the UBMs 126. The conductive connectors 128 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 128 may include a conductive material such as solder, copper, aluminum, gold, nickel, silver, palladium, tin, the like, or a combination thereof. In some embodiments, the conductive connectors 128 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 128 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. The conductive connectors 128 may be used to electrically and physically couple the integrated chip package 10 to other external devices (e.g., a package substrate, or the like).

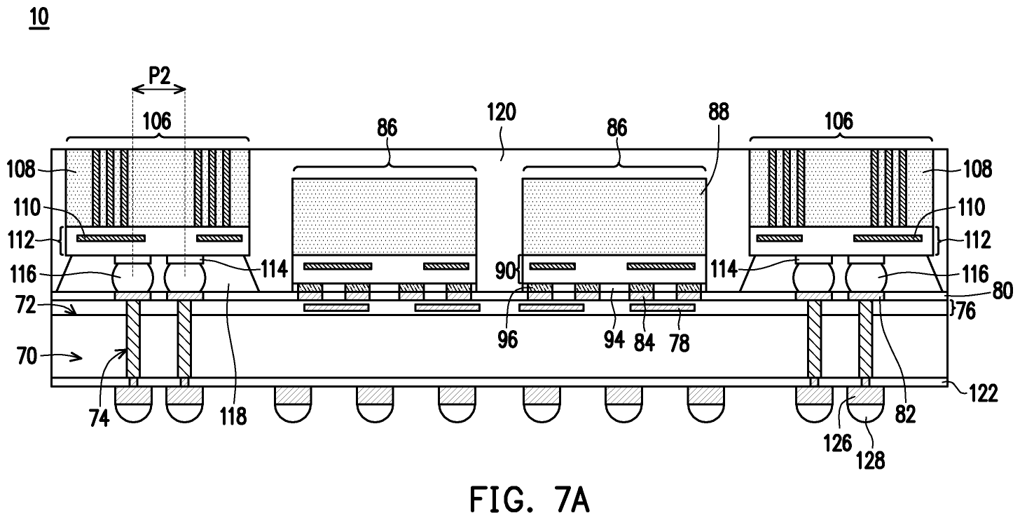

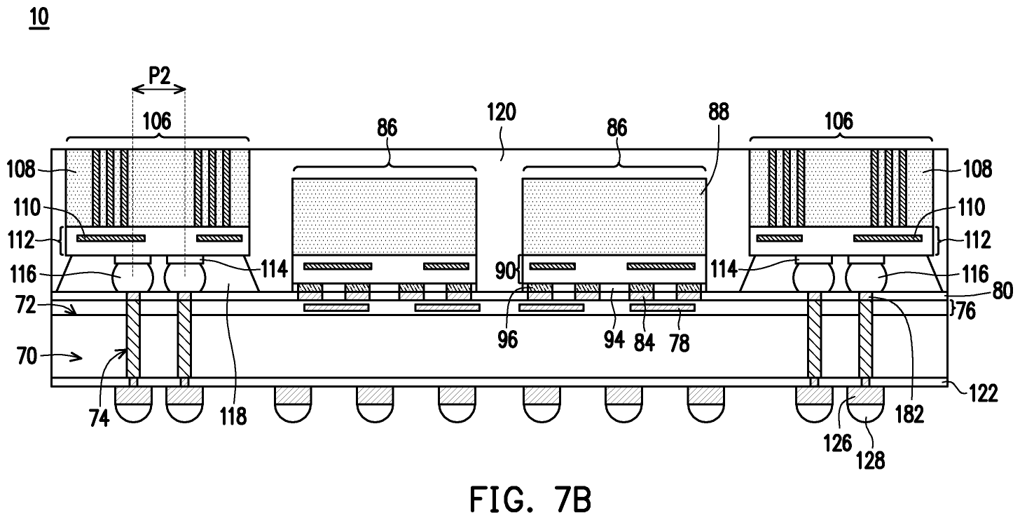

FIG. 7A illustrates the integrated chip package 10 in accordance with an alternative embodiment. Unless specified otherwise, like reference numerals in this embodiment (and subsequently discussed embodiments) represent like components in the embodiment shown in FIGS. 1 through 6 formed by like processes. Accordingly, the process steps and applicable materials may not be repeated herein. The embodiment of FIG. 7A is different from the embodiment of FIG. 6 in that in the embodiment of FIG. 7A, the formation of the first portion of the redistribution structure 98A and the second portion of the redistribution structure 98B is omitted. In addition, the formation of the UBMs 104 is also omitted. Instead, the conductive connectors 116 are formed on respective ones of the conductive pads 82 that are disposed in the bonding layer 80 on the package component 50. The conductive connectors 116 are electrically coupled to the redistribution structure 76 and the TVs 74 through the conductive pads 82. In other embodiments, the conductive connectors 116 are formed on respective ones of conductive vias 182 that are disposed in the bonding layer 80, as shown in FIG. 7B. After the formation of the conductive connectors 116, the semiconductor dies 106 are coupled to the conductive connectors 116 in a similar manner and using similar processes as were described previously in FIG. 4A, thereby making electrical connection between each semiconductor die 106 and the redistribution structure 76 and TVs 74 through the conductive pads 82 or the conductive vias 182.

The embodiments of the present disclosure have some advantageous features. The embodiments include a method applied to the formation of a device package, wherein the method comprises bonding at least one first semiconductor die (e.g., a first top die) to an interposer using a hybrid bonding configuration, wherein first bonding pads of the first semiconductor die are bonded to and electrically connected to second bonding pads on the interposer through direct metal-to-metal bonding. The hybrid bonding configuration also comprises directly bonding a first bonding layer of the first semiconductor die to a second bonding layer on the interposer using a dielectric-to-dielectric bond. The method further comprises coupling and electrically connecting at least one second semiconductor die (e.g., a second top die) to the interposer using first conductive connectors, such as micro bumps, or the like. The first bonding pads and the second bonding pads may have a first pitch that is less than 9 μm, wherein the first pitch is a distance from the center of a first bonding pad or a second bonding pad to the center of an adjacent first bonding pad or second bonding pad, respectively. The first conductive connectors may have a second pitch (e.g., greater than 30 μm) that is greater than the first pitch wherein the second pitch is a distance from the center of a first conductive connector to the center of an adjacent first conductive connector. One or more embodiments disclosed herein may include allowing the bonding of semiconductor dies having different interconnection bandwidth requirements to the interposer. For example, the first semiconductor die may be a graphics processing unit (GPU), central processing unit (CPU), or the like that requires a high input/output signal transfer capability. Because the first pitch is less than 9 μm, a greater number of the first bonding pads and second bonding pads that bond the first semiconductor die to the interposer can be utilized per unit area of the first semiconductor die and the interposer, which allows for greater interconnection bandwidths and faster signal transmission between the first semiconductor die and the interposer. As a result of the greater number of the first bonding pads and second bonding pads being utilized per unit area of the first semiconductor die and the interposer, a size of the device package can be reduced as compared to if other types of conductive connectors (e.g., solder bumps) having a greater pitch than the first pitch are used to bond the first semiconductor die to the interposer. The second semiconductor die may be a memory die, or the like, that may not require as high a signal transfer capability. It then becomes sufficient to use the first conductive connectors that have the second pitch to couple the second semiconductor die to the interposer, while still fulfilling interconnection bandwidth requirements. In addition, the use of the first conductive connectors to couple the second semiconductor die to the interposer results in lower manufacturing costs, and also results in better electrical connection between the second semiconductor die and the interposer, which improves device yield and reliability. Therefore, forming the device package by combining the use of the first and second bonding pads and the first and second bonding layers to bond the first semiconductor die (e.g., having high interconnection bandwidth requirements) to the interposer, and using the first conductive connectors to couple the second semiconductor die (e.g., having lower interconnection bandwidth requirements than the first semiconductor die) to the interposer may allow for the overall reduction of the device package size, a reduction in manufacturing costs, and an improved device yield and reliability of the device package.

In accordance with an embodiment, a package includes a first die over and bonded to a first side of a package component, where a first bond between the first die and the package component includes a dielectric-to-dielectric bond between a first bonding layer of the first die and a the second bonding layer on the package component, and second bonds between the first die and the package component include metal-to-metal bonds between first bonding pads of the first die and second bonding pads on the package component; a first portion of a redistribution structure adjacent to the first die and over the second bonding layer; and a second die over and coupled to the first portion of the redistribution structure using first conductive connectors, where the first conductive connectors are electrically connected to first conductive pads in the second bonding layer. In an embodiment, a first pitch of the first bonding pads is less than 9 μm. In an embodiment, a second pitch of the first conductive connectors is greater than the first pitch of the first bonding pads. In an embodiment, the second pitch of the first conductive connectors is greater than 30 μm. In an embodiment, the package component includes an interposer, and where the interposer includes a semiconductor substrate. In an embodiment, the package component includes an active die. In an embodiment, the first die includes a logic die, and the second die includes a memory die. In an embodiment, the package further includes an underfill disposed between the second die and the first portion of the redistribution structure.

In accordance with an embodiment, a package includes a first multi-chip stack over and bonded to a first side of an interposer, where a first bond between the first multi-chip stack and the interposer includes a dielectric-to-dielectric bond between a first bonding layer of the first multi-chip stack and a second bonding layer on the interposer, where the first multi-chip stack includes a first die; and a second die over and bonded to a first side of the first die, where a second bond between the first die and the second die includes a dielectric-to-dielectric bond between a third bonding layer of the second die and a fourth bonding layer on the first die; and a third die over and coupled to the first side of the interposer using first conductive connectors, where the first conductive connectors include solder micro bumps. In an embodiment, third bonds between the first multi-chip stack and the interposer include metal-to-metal bonds between first bonding pads of the multi-chip stack and second bonding pads on the interposer, and where fourth bonds between the first die and the second die include metal-to-metal bonds between third bonding pads of the second die and fourth bonding pads on the first die. In an embodiment, a first pitch of the first bonding pads and the second bonding pads is less than 9 μm, and a second pith of the first conductive connectors is greater than 30 μm. In an embodiment, the package further includes a first portion of a redistribution structure disposed between the interposer and the third die. In an embodiment, the package further includes an underfill disposed between the first portion of the redistribution structure and the third die, where the underfill surrounds the first conductive connectors. In an embodiment, a top surface of the first multi-chip stack is below a top surface of the third die. In an embodiment, the first die and the second die include logic dies, and the third die includes a memory die.

In accordance with an embodiment, a method of manufacturing a semiconductor device includes bonding a first die to a package component, where bonding the first die to the package component includes directly bonding a first dielectric layer of the first die to a second dielectric layer on the package component, and directly bonding first conductive connectors of the first die to second conductive connectors on the package component; forming a first portion of a redistribution structure adjacent to the first die and over the second dielectric layer; and coupling a second die to the first portion of the redistribution structure using third conductive connectors, where a first pitch of the first conductive connectors and the second conductive connectors is less than a second pitch of the third conductive connectors. In an embodiment, the method further includes forming an underfill that is disposed between the first portion of the redistribution structure and the second die, and where the underfill surrounds the third conductive connectors. In an embodiment, the method further includes encapsulating the first die and the second die in an encapsulant, where the encapsulant is disposed between the first portion of the redistribution structure and the second die, and where the encapsulant surrounds the third conductive connectors. In an embodiment, the method further includes planarizing the encapsulant to expose a top surface of the second die, where after the planarizing, a top surface of the first die is below the top surface of the second die. In an embodiment, the package component includes an active die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a first die over and bonded to a first side of a package component, wherein a first bond between the first die and the package component comprises a dielectric-to-dielectric bond between a first bonding layer of the first die and a the second bonding layer on the package component, and second bonds between the first die and the package component comprise metal-to-metal bonds between first bonding pads of the first die and second bonding pads on the package component;
a first portion of a redistribution structure adjacent to the first die and over the second bonding layer; and
a second die over and coupled to the first portion of the redistribution structure using first conductive connectors, wherein the first conductive connectors are electrically connected to first conductive pads in the second bonding layer.

2. The package of claim 1, wherein a first pitch of the first bonding pads is less than 9 μm.

3. The package of claim 2, wherein a second pitch of the first conductive connectors is greater than the first pitch of the first bonding pads.

4. The package of claim 3, wherein the second pitch of the first conductive connectors is greater than 30 μm.

5. The package of claim 1, wherein the package component comprises an interposer, and wherein the interposer comprises a semiconductor substrate.

6. The package of claim 1, wherein the package component comprises an active die.

7. The package of claim 1, wherein the first die comprises a logic die, and the second die comprises a memory die.

8. The package of claim 1, further comprising an underfill disposed between the second die and the first portion of the redistribution structure.

9. A package comprising:
a first multi-chip stack over and bonded to a first side of an interposer, wherein a first bond between the first multi-chip stack and the interposer comprises a dielectric-to-dielectric bond between a first bonding layer of the first multi-chip stack and a second bonding layer on the interposer, wherein the first multi-chip stack comprises:
a first die; and
a second die over and bonded to a first side of the first die, wherein a second bond between the first die and the second die comprises a dielectric-to-dielectric bond between a third bonding layer of the second die and a fourth bonding layer on the first die; and
a third die over and coupled to the first side of the interposer using first conductive connectors, wherein the first conductive connectors comprise solder micro bumps.

10. The package of claim 9, wherein third bonds between the first multi-chip stack and the interposer comprise metal-to-metal bonds between first bonding pads of the multi-chip stack and second bonding pads on the interposer, and wherein fourth bonds between the first die and the second die comprise metal-to-metal bonds between third bonding pads of the second die and fourth bonding pads on the first die.

11. The package of claim 10, wherein a first pitch of the first bonding pads and the second bonding pads is less than 9 μm, and a second pith of the first conductive connectors is greater than 30 μm.

12. The package of claim 9, further comprising a first portion of a redistribution structure disposed between the interposer and the third die.

13. The package of claim 12, further comprising an underfill disposed between the first portion of the redistribution structure and the third die, wherein the underfill surrounds the first conductive connectors.

14. The package of claim 13, wherein a top surface of the first multi-chip stack is below a top surface of the third die.

15. The package of claim 9, wherein the first die and the second die comprise logic dies, and the third die comprises a memory die.

16. A method of manufacturing a semiconductor device, the method comprising:
bonding a first die to a package component, wherein bonding the first die to the package component comprises directly bonding a first dielectric layer of the first die to a second dielectric layer on the package component, and directly bonding first conductive connectors of the first die to second conductive connectors on the package component;
forming a first portion of a redistribution structure adjacent to the first die and over the second dielectric layer; and
coupling a second die to the first portion of the redistribution structure using third conductive connectors, wherein a first pitch of the first conductive connectors and the second conductive connectors is less than a second pitch of the third conductive connectors.

17. The method of claim 16, further comprising forming an underfill that is disposed between the first portion of the redistribution structure and the second die, and wherein the underfill surrounds the third conductive connectors.

18. The method of claim 16, further comprising encapsulating the first die and the second die in an encapsulant, wherein the encapsulant is disposed between the first portion of the redistribution structure and the second die, and wherein the encapsulant surrounds the third conductive connectors.

19. The method of claim 18, further comprising:
planarizing the encapsulant to expose a top surface of the second die, wherein after the planarizing, a top surface of the first die is below the top surface of the second die.

20. The method of claim 16, wherein the package component comprises an active die.
